(19) United States
(12) Patent Application Publication
(10) Pub. No.: US 2025/0107191 A1
(43) Pub. Date: Mar. 27, 2025

(54) SEMICONDUCTOR DEVICE INCLUDING NOBLE METAL TWO-DIMENSIONAL MATERIAL

(71) Applicants: Samsung Electronics Co., Ltd., Suwon-si (KR); KOREA ADVANCED INSTITUTE OF SCIENCE AND TECHNOLOGY, Daejeon (KR)

(72) Inventors: Minseok YOO, Suwon-si (KR); Kibum KANG, Daejeon (KR); Minseung GYEON, Daejeon (KR); Minsu SEOL, Suwon-si (KR)

(73) Assignees: Samsung Electronics Co., Ltd., Suwon-si (KR); KOREA ADVANCED INSTITUTE OF SCIENCE AND TECHNOLOGY, Daejeon (KR)

(21) Appl. No.: 18/897,189

(22) Filed: Sep. 26, 2024

(30) Foreign Application Priority Data
Sep. 27, 2023 (KR) 10-2023-0131160

(51) Int. Cl. H01L 29/24; H01L 29/08; H01L 29/10; H01L 29/66; H01L 29/786

(52) U.S. Cl. CPC H10D 62/80; H10D 30/675; H10D 30/6757; H10D 62/151; H10D 62/235; H10D 99/00

(57) ABSTRACT

A semiconductor device may include a channel layer including a channel region, a source region, and a drain region, the source region and the drain region being on both sides of the channel region, respectively; a source electrode connected to the source region, a drain electrode connected to the drain region, and a gate electrode on the channel region. The channel region may include a first two-dimensional material layer including a noble metal-based two-dimensional semiconductor material and a second two-dimensional material layer including a two-dimensional semiconductor material different from the first two-dimensional material layer.

### CROSS-REFERENCE TO RELATED APPLICATION

This application is based on and claims priority under 35 U.S.C. § 119 to Korean Patent Application No. 10-2023-0131160, filed on Sep. 27, 2023 in the Korean Intellectual Property Office, the disclosure of which is incorporated by reference herein in its entirety.

### BACKGROUND

### 1. Field

The disclosure relates to a semiconductor device including a noble metal two-dimensional semiconductor material.

### 2. Description of the Related Art

As miniaturization is underway to improve the degree of integration of semiconductor devices, research using two-dimensional materials has recently been conducted. Two-dimensional materials refer to crystalline materials having thicknesses of a few atomic layers or less. Two-dimensional materials are being studied as materials to replace silicon. Furthermore, two-dimensional materials are attracting attention as next-generation materials that can overcome performance degradation, caused by miniaturization of semiconductor devices, because they are stable and have excellent properties even in nano-scale thickness.

### SUMMARY

Provided is a semiconductor device including a noble metal two-dimensional semiconductor material.

Additional aspects will be set forth in part in the description which follows and, in part, will be apparent from the description, or may be learned by practice of the presented embodiments of the disclosure.

According to an example embodiment, a semiconductor device may include a channel layer including a channel region, a source region, and a drain region, the source region and the drain region on both sides of the channel region, respectively; a source electrode connected to the source region; a drain electrode connected to the drain region; and a gate electrode on the channel region. The channel region may include a first two-dimensional material layer and a second two-dimensional material layer. The first two-dimensional material layer may include a noble metal-based two-dimensional semiconductor material. The second two-dimensional material layer may include a two-dimensional semiconductor material. The two-dimensional semiconductor material of the second two-dimensional material layer may be different from the noble metal-based two-dimensional semiconductor material of the first two-dimensional material layer.

In some embodiments, the first two-dimensional material layer may include at least one of Pt, Ag, Pd, Ir, Ru, Au, Os, and Rd and the first two-dimensional material layer may include at least one of S, Se, and Te.

In some embodiments, the second two-dimensional material layer may include a transition metal dichalcogenide (TMD) material.

In some embodiments, the TMD material may include at least one of Mo, W, Nb, V, Ta, Ti, Zr, Hf, Tc, Re, Cu, Ga, In, Sn, Ge, and Pb, and the TMD material may include at least one of S, Se, and Te.

In some embodiments, the first two-dimensional material layer may be arranged on each of an uppermost portion of the channel layer and a lowermost portion of the channel layer.

In some embodiments, a number of layers of the first two-dimensional material layer on each of the uppermost portion of the channel layer and the lowermost portion of the channel layer may be one to three.

In some embodiments, a number of layers of the second two-dimensional material layer may be one to ten.

In some embodiments, the source region and the drain region each may include the first two-dimensional material layer and the second two-dimensional material layer.

In some embodiments, the source region and the drain region each may include the first two-dimensional material layer in plural form to provide a plurality of the first two-dimensional material layers.

In some embodiments, a portion of the plurality of first two-dimensional material layers may form a lateral junction with the second two-dimensional material layer.

In some embodiments, a number of layers of the plurality of first two-dimensional material layers may be four or more.

In some embodiments, the gate electrode may be on an upper portion of the channel region or a lower portion of the channel region.

According to an example embodiment, a semiconductor device may include a first channel layer including a first channel region, a first source region, and a first drain region, the first source region and the first drain region being provided on both sides of the first channel region, respectively; a second channel layer spaced apart from the first channel layer and including a second channel region, a second source region, and a second drain region, the second source region and the second drain region being respectively provided on both sides of the second channel region; a source electrode connected to the first source region and the second source region; a drain electrode connected to the first drain region and the second drain region; and a gate electrode surrounding the first channel region and the second channel region. The first channel region and the second channel region each may include a first two-dimensional material layer including a noble metal-based two-dimensional semiconductor material and a second two-dimensional material layer including a two-dimensional semiconductor material different from the first two-dimensional material layer.

In some embodiments, the first two-dimensional material layer may include at least one of Pt, Ag, Pd, Ir, Ru, Au, Os, and Rd, and the first two-dimensional material layer may include at least one of S, Se, and Te.

In some embodiments, the second two-dimensional material layer may include a transition metal dichalcogenide (TMD) material.

In some embodiments, the TMD material may include at least one of Mo, W, Nb, V, Ta, Ti, Zr, Hf, Tc, Re, Cu, Ga, In, Sn, Ge, and Pb, and the TMD material may include at least one of S, Se, and Te.

In some embodiments, the first two-dimensional material layer may be on each of an uppermost portion of the first channel layer, an uppermost portion of the second channel layer, a lowermost portion of the first channel layer, and a lowermost portion of the second channel layer.

In some embodiments, the source region and the drain region each may include the first two-dimensional material layer and the second two-dimensional material layer.

In some embodiments, the first source region and the first drain region each may include the first two-dimensional material in plurality form to provide a plurality of the first two-dimensional material layers.

In some embodiments, a portion of the plurality of first two-dimensional material layers may form a lateral junction with the second two-dimensional material layer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a cross-sectional view illustrating a semiconductor device according to an embodiment;

FIG. 2 is a cross-sectional view illustrating a semiconductor device according to another embodiment;

FIG. 3 is a cross-sectional view illustrating a semiconductor device according to another embodiment;

FIG. 4 is a cross-sectional view illustrating a semiconductor device according to another embodiment;

FIG. 5 is a cross-sectional view illustrating a semiconductor device according to another embodiment;

FIG. 6 is a cross-sectional view illustrating a semiconductor device according to another embodiment;

FIG. 7 is a cross-sectional view illustrating a semiconductor device according to another embodiment;

FIGS. 8A and 8B are cross-sectional views illustrating a semiconductor device according to another embodiment;

FIG. 9 is a cross-sectional view taken along line A-A′ of FIGS. 8A and 8B;

FIG. 10 is a schematic block diagram of a display driver integrated circuit (IC) (DDI) and a display device including a DDI, according to an embodiment;

FIG. 11 is a circuit diagram of a CMOS inverter according to an embodiment;

FIG. 12 is a circuit diagram of a CMOS SRAM device according to an embodiment;

FIG. 13 is a circuit diagram of a CMOS NAND circuit according to an embodiment;

FIG. 14 is a block diagram of an electronic device according to an embodiment; and

FIG. 15 is a block diagram of an electronic device according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C”, “at least one of A, B, or C”) may be construed as A only, B only, C only, or any combination of two or more of A, B, and C, such as, for instance, ABC, AB, BC, and AC.

Hereinafter, embodiments will be described in detail with reference to the accompanying drawings. In the following drawings, the same reference numerals refer to the same components, and the size of each component in the drawings may be exaggerated for clarity and convenience of description. Meanwhile, embodiments described below are merely illustrative, and various modifications are possible from these embodiments.

Hereinafter, the term “upper portion” or “on” may also include “to be present on the top, bottom, left or right portion on a non-contact basis” as well as “to be present just on the top, bottom, left or right portion in directly contact with”. Singular expressions include plural expressions unless the context clearly means otherwise. In addition, when a part “contains” a component, this means that it may contain other components, rather than excluding other components, unless otherwise stated.

The use of the term “the” and similar indicative terms (e.g., “a” and “an”) may correspond to both singular and plural. Unless there is clear order or contrary description of the steps constituting the method, these steps may be performed in the appropriate order, and are not necessarily limited to the order described.

Further, the terms “unit”, “module” or the like mean a unit that processes at least one function or operation, which may be implemented in hardware or software or implemented in a combination of hardware and software.

The connection or connection members of lines between the components shown in the drawings are non-limiting examples and may represent functional connection and/or physical or circuit connections, and may be replaceable or represented as various additional functional connections, physical connections, or circuit connections in an actual device.

The use of all examples or illustrative terms is simply to describe technical ideas in detail, and the scope is not limited due to these examples or illustrative terms unless the scope is limited by the claims.

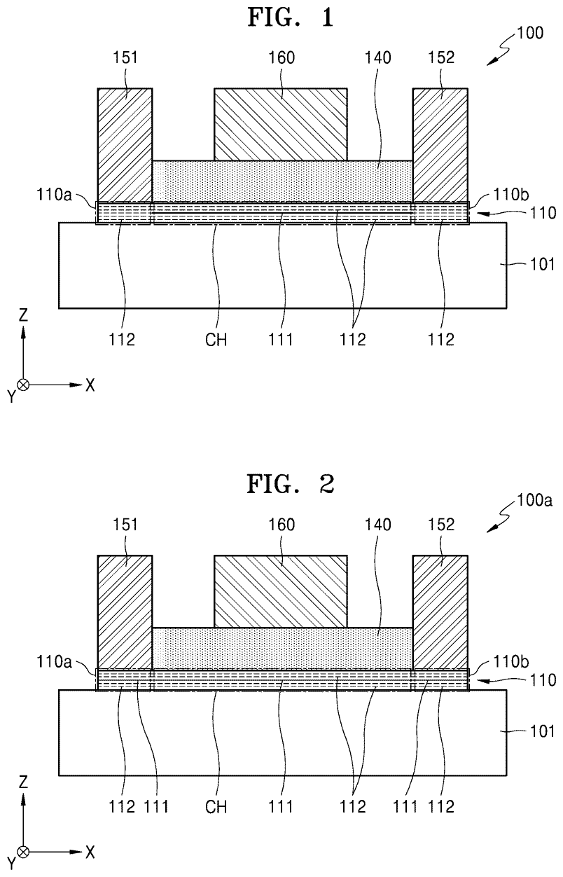

FIG. 1 is a cross-sectional view illustrating a semiconductor device according to an embodiment.

The semiconductor device 100 shown in FIG. 1 may include, for example, a field effect transistor (FET).

Referring to FIG. 1, a channel layer 110 is provided on a substrate 101. The substrate 101 may include various materials, such as a semiconductor material, an insulating material, a metal material, and the like. When a first two-dimensional material layer 112 or a second two-dimensional material layer 111 to be described later is formed by depositing a two-dimensional semiconductor material on the substrate 101, the substrate 101 may be a substrate for growing the two-dimensional semiconductor material.

A channel layer 110 may include a two-dimensional semiconductor material. Here, the two-dimensional semiconductor material refers to a two-dimensional material having a layered structure in which constituent atoms are two-dimensionally bonded and semiconductor properties.

The channel layer 110 may include a channel region CH and a source region 110a and a drain region 110b respectively provided on both sides of the channel region CH. A source electrode 151 may be electrically connected to the source region 110a, and a drain electrode 152 may be electrically connected to the drain region 110b. A gate insulating layer 140 and a gate electrode 160 are sequentially stacked on the channel region CH between the source region 110a and the drain region 110b.

The channel region CH may include at least one first two-dimensional material layer 111 and at least one second two-dimensional material layer 112. The first two-dimensional material layer 111 may include a two-dimensional semiconductor material based on a noble metal. The first two-dimensional semiconductor material layer 111 may include a noble metal element and a chalcogen element. Here, the noble metal element may include, for example, at least one of Pt, Ag, Pd, Ir, Ru, Au, Os, and Rd. In addition, the chalcogen element may include, for example, at least one of S, Se, and Te. As a specific example, the first two-dimensional material layer 112 may include PtS₂ and PtSe₂, but is not limited thereto.

The first two-dimensional material layer 112 including the noble metal-based two-dimensional semiconductor material may have semiconductor properties or semi-metallic properties according to the number of layers. The noble metal-based two-dimensional semiconductor material may have higher material stability than other two-dimensional materials, and may easily form a junction structure with other two-dimensional semiconductor materials due to the structure of the two-dimensional material layer. A vertical bonding between the two-dimensional semiconductor material and the two-dimensional semi-metal material may effectively reduce contact resistance by minimizing a metal-induced gap state (MIGS) and a defect-induced gap state (DIGS).

The second two-dimensional material layer 111 may include a two-dimensional semiconductor material different from the first two-dimensional material layer 112. The second two-dimensional material layer 111 may include a two-dimensional semiconductor material having a band gap of about 0.5 eV to about 3.0 eV.

The second-dimensional material layer 111 may include a two-dimensional semiconductor material layer having a polycrystalline structure. Here, the two-dimensional semiconductor material refers to a two-dimensional material having a layered structure in which constituent atoms are two-dimensionally coupled. The two-dimensional semiconductor material has excellent electrical properties and may maintain high mobility without greatly changing its characteristics even when the thickness is reduced to a nano scale.

The TMD is a two-dimensional material having semiconductor properties and is a compound of a transition metal and a chalcogen element. Here, the transition metal may include, for example, at least one of Mo, W, Nb, V, Ta, Ti, Zr, Hf, Co, Tc, and Re, and the chalcogen element may include, for example, at least one of S, Se, and Te. As a specific example, the TMD may include MoS₂, MoSe₂, MoTe₂, WS₂, WSe₂, WTe₂, ZrS₂, ZrSe₂, HfS₂, HfSe₂, NbSe₂, ReSe₂, and the like. However, the embodiments are not limited thereto.

The second two-dimensional material layer 111 may include, for example, black phosphorus. The black phosphorus is a two-dimensional semiconductor material having a structure in which phosphorus (P) atoms are two-dimensionally coupled. At least one of the first and second two-dimensional material layers may further include a p-type dopant or an n-type dopant to control mobility. The black phosphorus is a semiconductor material having a structure in which phosphorus (P) atoms are two-dimensionally coupled.

At least one of the first two-dimensional material layer 112 and the second two-dimensional material layer 111 may be doped with a p-type dopant or an n-type dopant to control mobility. The first two-dimensional material layer 112 or the second two-dimensional material layer 111 may have a monolayer or multilayer structure, and here, each layer may have an atomic level thickness.

The channel region CH may include at least one first two-dimensional material layer 112 and at least one second two-dimensional material layer 111 stacked in a thickness direction of the substrate 101. Here, a first two-dimensional material layer 112 may be arranged on each of the uppermost and lowermost portions of the channel region. Since the noble metal-based two-dimensional semiconductor material may have metallic properties when formed of four or more layers, the first two-dimensional material layer 112 arranged at each of the uppermost and lowermost portions of the channel region may include 1 to 3 layers. In FIG. 1, a case in which the first two-dimensional material layer 112 includes two layers respectively arranged on the uppermost and lowermost portions of the channel layer 110 is illustrated as an example.

A second two-dimensional material layer 111 may be arranged in a center portion of the channel region CH. The second two-dimensional material layer 111 may include, for example, 1 to 10 layers. However, this is merely illustrative. In FIG. 1, a case where the second two-dimensional material layer 111 includes one layer is illustrated as an example. As such, the channel region may be easily protected from the outside by providing the first two-dimensional material layers 112 including a noble metal-based two-dimensional semiconductor material with high material stability at the uppermost and lowermost portions of the channel region, respectively.

A source region 110a and a drain region 110b are provided at both sides of the channel region CH, respectively. Each of the source region 110a and the drain region 110b may include a plurality of first two-dimensional material layers 112. Here, the first two-dimensional material layer 112 may include a noble metal-based two-dimensional semiconductor material as described above.

The first two-dimensional material layers 112 in the source region 110a and the drain region 110b may be provided to extend from both sides of the first and second two-dimensional material layers in the channel region CH. In this case, some of the first two-dimensional material layers 112 in the source region 110a and the drain region 110b may be provided to be in a lateral junction with the second two-dimensional material layer 111.

Since the noble metal-based two-dimensional semiconductor material may have metallic properties when formed of four or more layers, the first two-dimensional material layer 112 provided in each of the source region 110a and the drain region 110b may include four or more layers. Accordingly, contact resistance between the source electrode 151 and the source region 110a and contact resistance between the drain electrode 152 and the drain region 110b may be reduced.

The first two-dimensional material layer 112 and the second two-dimensional material layer 111 may be stacked in a cross-linked form, and the stacking orientation may be 0° to 120°, but is not limited thereto.

A gate insulating layer 140 and a gate electrode 160 may be sequentially stacked above the channel layer 110. The gate insulating layer 140 may include, for example, silicon nitride, or the like, but is not limited thereto.

The gate electrode 160 may include metal material or conductive oxide. Here, the metallic material may include, for example, at least one selected from the group consisting of Au, Ti, TiN, TaN, W, Mo, WN, Pt, and Ni. In addition, the conductive oxide may include, for example, Indium Tin Oxide (ITO), Indium Zinc Oxide (IZO), etc. However, this is merely illustrative.

A source electrode 151 and a drain electrode 152 are provided on both sides of the gate electrode 160, respectively. The source electrode 151 and the drain electrode 152 are respectively provided in the source region 110a and the drain region 110b of the channel layer 110. Here, the source electrode 151 may be provided to be in contact with the source region 110a of the channel layer 110, and the drain electrode 152 may be provided to be in contact with the drain region 110b of the channel layer 110. The source electrode 151 and the drain electrode 152 may include, for example, a metal material having excellent electrical conductivity, such as Ag, Au, Pt, or Cu, but are not limited thereto.

In existing silicon-based semiconductor devices, as a channel thickness decreases, mobility may decrease, threshold voltage distribution may increase; and as channel length decreases, performance degradation due to the short channel effect may increase. Accordingly, there is a limit to reducing the size of semiconductor devices.

The semiconductor device 100 according to the present embodiment may have excellent performance even in a thin thickness of 1 nm or less by using a two-dimensional semiconductor material as a channel, and may also reduce the short channel effect, thereby overcoming the limitation of performance degradation due to miniaturization of the semiconductor device 100.

FIG. 2 is a cross-sectional view illustrating a semiconductor device 100a according to another embodiment.

Referring to FIG. 2, a source region 110a and a drain region 110b may be respectively arranged on both sides of a channel region CH, and a channel layer 110 including all of the channel region CH, the source region 110a, and the drain region 110b may be provided. A source electrode 151 and a drain electrode 152 may be electrically connected to the source region 110a and the drain region 110b, respectively, and a gate electrode 160 may be provided on the channel region CH. The channel region CH may include at least one first two-dimensional material layer 112 including a noble metal-based two-dimensional semiconductor material and at least one second two-dimensional material layer 111 including a two-dimensional semiconductor material different from the first two-dimensional semiconductor material layer 112. The source region 110a and the drain region 110b may include at least one first two-dimensional material layer 112 and at least one second two-dimensional material layer 111 including a two-dimensional semiconductor material different from the first two-dimensional material layer 112.

Unlike the one described with reference to FIG. 1, the second two-dimensional material layer 111 may be arranged in the source region 110a and the drain region 110b as well as the channel region CH. Other contents are the same as described with reference to FIG. 1.

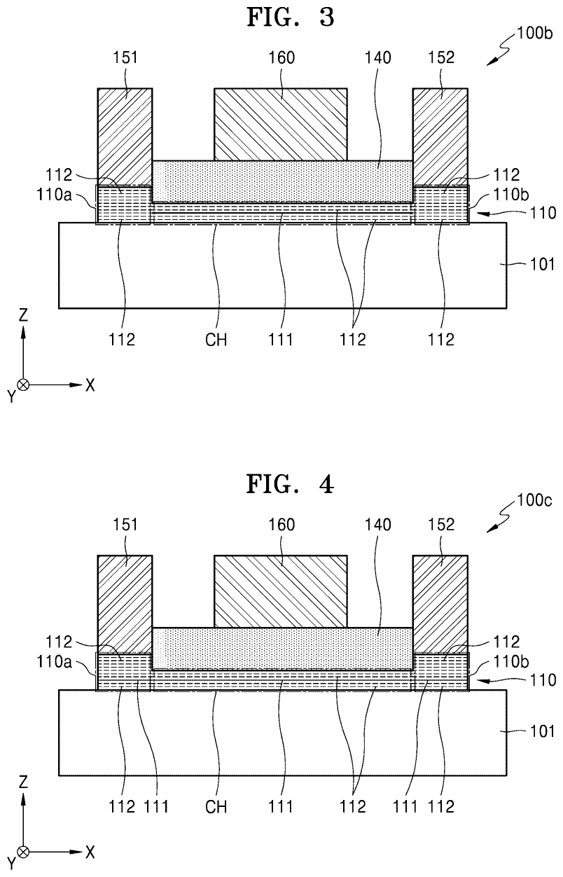

FIG. 3 is a cross-sectional view illustrating a semiconductor device 100b according to another embodiment.

Referring to FIG. 3, the channel region CH may include at least one first two-dimensional material layer 112 including a noble metal-based two-dimensional semiconductor material and at least one second two-dimensional material layer 111 including a two-dimensional semiconductor material different from the first two-dimensional semiconductor material layer 112.

A source region 110a and a drain region 110b may include at least one first two-dimensional material layer 112. The first two-dimensional material layer 112 provided in the source region 110a and the drain region 110b may be provided in a plurality of layers, and the number of layers of the first two-dimensional material layer 112 may be 4 or more. As the number of layers of the first two-dimensional material layer 112 increases, the thicknesses of the source region 110a and the drain region 110b may become greater than the thickness of the channel region CH, and as the thicknesses of the source region 110a and the drain region 110b increases, the contact resistance of the source electrode 151 and the drain electrode 152 decreases, thereby improving the performance of the semiconductor device.

Some of the plurality of first two-dimensional material layers 112 provided in the source region 110a and the drain region 110b may form a lateral junction with the second two-dimensional material layer 111 provided in the channel region CH. Since the first two-dimensional material layer 112 and the second two-dimensional material layer 111 forming the lateral junction form the lateral junction on the same layer or surface, a two-dimensional lateral junction may be formed. Other contents are the same as described with reference to FIGS. 1 and 2.

FIG. 4 is a cross-sectional view illustrating a semiconductor device 100c according to another embodiment.

Referring to FIG. 4, a source region 110a and a drain region 110b may be respectively arranged on both sides of a channel region CH, and a channel layer 110 including all of the channel region CH, the source region 110a, and the drain region 110b may be provided. A source electrode 151 and a drain electrode 152 may be electrically connected to the source region 110a and the drain region 110b, respectively, and a gate electrode 160 may be provided on the channel region CH. The channel region CH may include at least one first two-dimensional material layer 112 including a noble metal-based two-dimensional semiconductor material and at least one second two-dimensional material layer 111 including a two-dimensional semiconductor material different from the first two-dimensional semiconductor material layer 112. The source region 110a and the drain region 110b may include at least one first two-dimensional material layer 112 and at least one second two-dimensional material layer 111 including a two-dimensional semiconductor material different from the first two-dimensional material layer 112.

In addition, the second two-dimensional material layer 111 provided in the channel region CH and the second two-dimensional material layers 111 provided in the source region 110a and the drain region 110b may be provided on the same surface or layer.

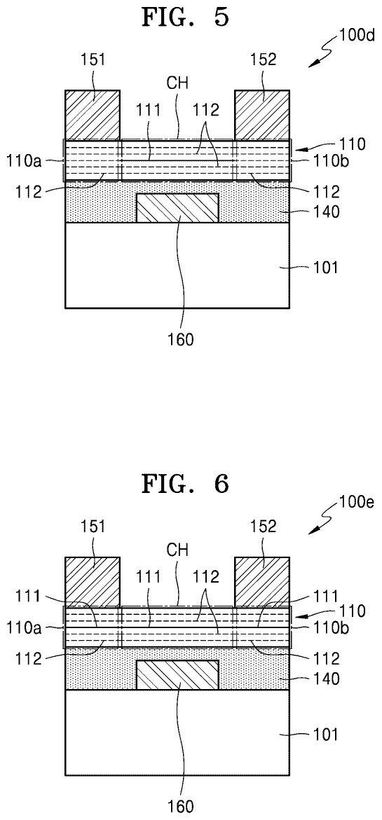

FIG. 5 is a cross-sectional view illustrating a semiconductor device 100d according to another embodiment.

Referring to FIG. 5, a gate electrode 160 and a gate insulating layer 140 are provided on a substrate 101, a channel layer 110 is provided above the gate electrode 160 and on the gate insulating layer 140, and the channel layer 110 may include a channel region CH, a source region 110a, and a drain region 110b. In other words, the gate electrode 160 and the gate insulating layer 140 may be arranged below the channel layer 110.

The channel region CH may include a second two-dimensional material layer 111 and a first two-dimensional material layer 112, and a single or multiple second two-dimensional material layers 111 may be provided at upper and lower portions of the second two-dimensional material layer 111 included in the channel region, respectively. The second two-dimensional material layer 111 provided in the channel region CH may be 1 to 3 layers on upper and lower portions, respectively.

The source region 110a and the drain region 110b may include a first two-dimensional material layer 112, and the first two-dimensional material layer 112 may be four or more layers, but is not limited thereto.

Some of the plurality of first two-dimensional material layers 112 provided in the source region 110a and the drain region 110b may form a lateral junction with the second two-dimensional material layer 111 provided in the channel region CH. Since the first two-dimensional material layer 112 and the second two-dimensional material layer 111 forming the lateral junction form the lateral junction on the same layer or surface, a two-dimensional lateral junction may be formed. Other contents are the same as described with reference to FIGS. 1 to 4.

FIG. 6 is a cross-sectional view illustrating a semiconductor device 100e according to another embodiment.

Referring to FIG. 6, a gate electrode 160 and a gate insulating layer 140 are provided on a substrate 101, a channel layer 110 is provided above the gate electrode 160 and on the gate insulating layer 140, and the channel layer 110 may include a channel region CH, a source region 110a, and a drain region 110b.

The channel region CH may include a second two-dimensional material layer 111 and a first two-dimensional material layer 112, and a single or multiple second two-dimensional material layers 111 may be provided at upper and lower portions of the second two-dimensional material layer 111 included in the channel region, respectively. The second two-dimensional material layer 111 provided in the channel region CH may be 1 to 3 layers on upper and lower portions, respectively. The source region 110a and the drain region 110b may include a first two-dimensional material layer 112 and a second two-dimensional material layer 111, and the first two-dimensional material layer 112 may be four or more layers, but is not limited thereto.

The second two-dimensional material layer 111 provided in the channel region CH and the second two-dimensional material layers 111 provided in the source region 110a and the drain region 110b may be provided on the same surface or layer. Other contents are the same as described with reference to FIGS. 1 to 5.

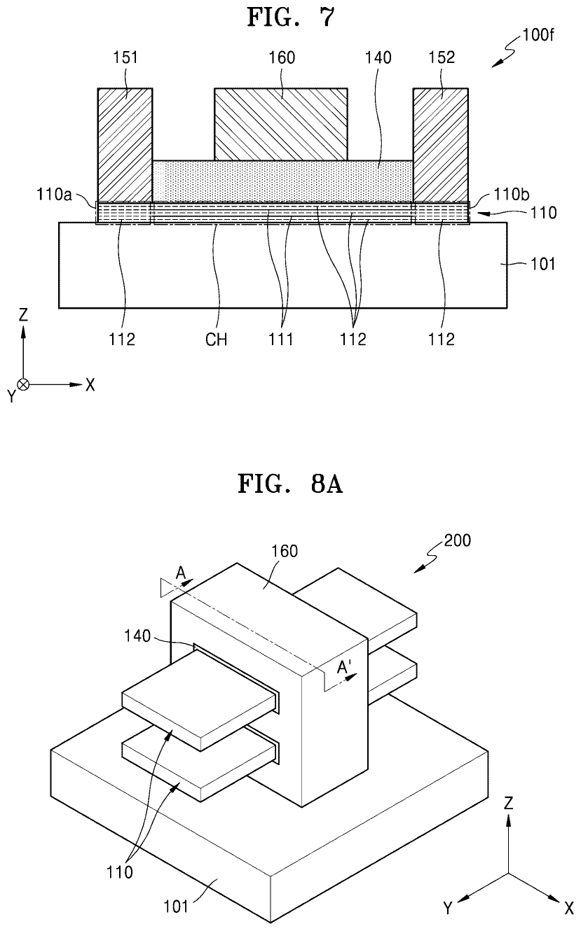

FIG. 7 is a cross-sectional view illustrating a semiconductor device 100f according to another embodiment.

Referring to FIG. 7, a source electrode 151 and a drain electrode 152 may be provided above the substrate 101, and a channel layer 110 connecting the source electrode 151 and the drain electrode 152 may be provided. The channel layer 110 may include a first two-dimensional material layer 112 and a second two-dimensional material layer 111. The first two-dimensional material layer 112 and the second two-dimensional material layer 111 provided in the channel region CH included in the channel layer 110 may be alternately stacked and arranged in the thickness direction of the channel region CH. At least one second two-dimensional material layer 111 may be arranged by being alternately stacked between the at least one first two-dimensional material layer 112. The number of layers of at least one of the first two-dimensional material layer 112 and the second two-dimensional material layer 111 may be 1 or more. Other contents are the same as described with reference to FIGS. 1 to 6.

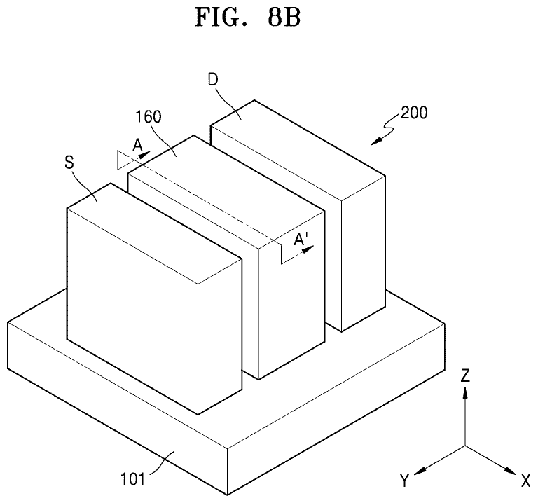

FIG. 8A is a cross-sectional view illustrating a semiconductor device according to another embodiment.

Referring to FIG. 8A, a perspective view illustrates a semiconductor device 200 such as a multi-bridge channel field effect transistor (MBCFET) according to another embodiment.

As technology advances, semiconductor devices have developed into a gate all-around (GAA) structure, starting from a sheet-shaped structure and passing over a FIM structure to manufacture high-integration transistors. The MBCFET is a type of GAA transistor structure, and refers to a structure in which a plurality of thin channel layers having a sheet-shaped structure are vertically stacked. A structure in which four surfaces of the plurality of sheet-shaped channel layers are formed to surround the gate electrode is referred to as an MBCFET structure.

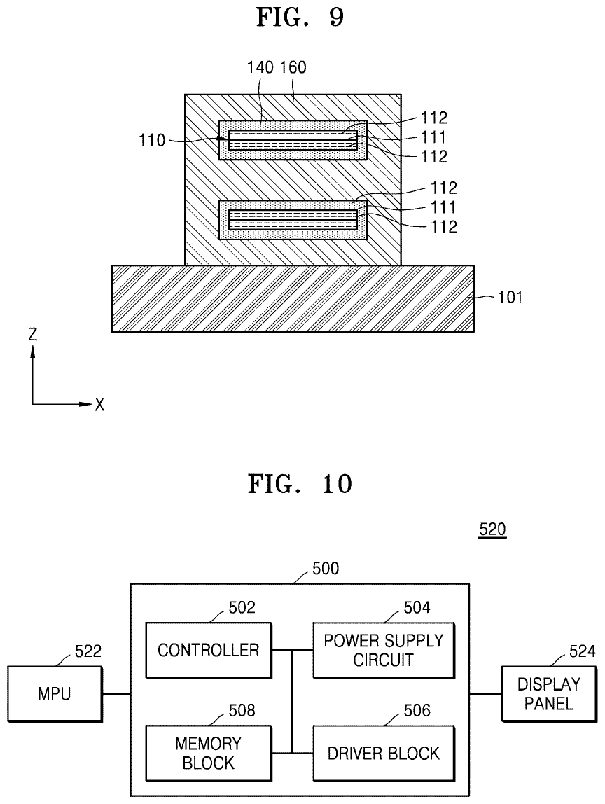

FIG. 9 is a cross-sectional view taken along line A-A′ of FIG. 8A.

Referring to FIGS. 8A and 9, at least one channel layer 110 is arranged on the substrate 101 to be spaced apart from the substrate 101. Here, each channel layer 110 may have a shape of a sheet arranged parallel to the substrate 101. In FIGS. 8A and 9, a case where two channel layers 110 are arranged vertically above the substrate 101 is illustrated.

A gate insulating layer 140 is provided to surround each channel layer 110, and a gate electrode 160 is provided on the gate insulating layer 140. Here, the gate insulating layer 140 may be provided to surround four surfaces of the channel layer 110, and the gate electrode 160 may be provided to surround four surfaces of the gate insulating layer 140. Although not shown in FIG. 8A, the source and drain electrodes may be respectively provided on the left and right sides of the channel layer 110. FIG. 8B illustrates the semiconductor device 200 including the source electrode S and drain electrode D covering respective end regions of the plurality of channel layers 110. The source electrode S, gate electrode 160, and drain electrode D are spaced apart from each other with the gate electrode 160 between the source electrode S and the drain electrode D.

Referring to FIG. 9, the gate electrode 160 is arranged on the substrate 101, the gate electrode 160 surrounds four surfaces of a plurality of channel layers 110 arranged in a thin sheet shape, the gate insulating layer 140 is arranged between the channel layer 110 and the gate electrode 160, and the gate insulating layer 140 may include a dielectric layer (not shown).

Specifically, a first channel layer including a first channel region, a first source region (not shown) and a first drain region (not shown) respectively provided on both sides of the first channel region, and a second channel layer including a second channel region provided to be spaced apart from the first channel layer, a second source region (not shown) and a second drain region respectively provided on both sides of the second channel region may be included. A source electrode (not shown) connected to the first source region (not shown) and the second source region (not shown) may be included. A drain electrode (not shown) connected to the first drain region (not shown) and the second drain region (not shown) may be included. A gate electrode may be provided to surround a plurality of channel layers 110 including the first channel region and the second channel region. Although FIG. 9 illustrates only the first channel layer and the second channel layer for convenience, the plurality of channel layers 110 are not necessarily limited to the first and second channel layers, and various channel layers may be provided.

More specifically, the plurality of channel layers 110 may be arranged to be spaced apart from each other, and the gate electrode 160 may be arranged between the plurality of channel layers 110. Each of the plurality of channel layers 110 may include a first two-dimensional material layer 112 and a second two-dimensional material layer 111, and at least one first two-dimensional material layer 112 may be arranged above and below the second two-dimensional material layer 111, and in this case, the number of layers of the first two-dimensional material layer 112 may be 1 to 3. Other contents are the same as described with reference to FIGS. 1 to 7.

FIG. 9 is a diagram showing an MBCFET structure, but is not limited thereto, and may include a field effect transistor having a fin FET structure and a planar structure.

FIG. 10 is a schematic block diagram of a display driver integrated circuit (IC) (DDI) and a display device including a DDI according to an embodiment.

Referring to FIG. 10, the display driving integrated circuit 500 may include a controller 502, a power supply circuit 504, a driver block 506, and a memory block 508. The controller 502 receives and decodes a command applied from a main processing unit (MPU) 522, and controls each of blocks of the DDI 500 to implement an operation according to the command. The power supply circuit 504 generates a driving voltage in response to the control of the controller 502. The driver block 506 drives the display panel 524 using the driving voltage generated by the power supply circuit 504 in response to the control of the controller 502. The display panel 524 may be, for example, a liquid crystal display panel, an organic light emitting device (OLED) display panel, or a plasma display panel. The memory block 508 is a block that temporarily stores commands input to the controller 502 or control signals output from the controller 502, or stores necessary data, and may include memories such as RAM and ROM.

The power supply circuit 504 and the driver block 506 may include any one of the semiconductor devices according to the embodiments described above with reference to FIGS. 1 to 9, or a semiconductor device modified and combined thereof.

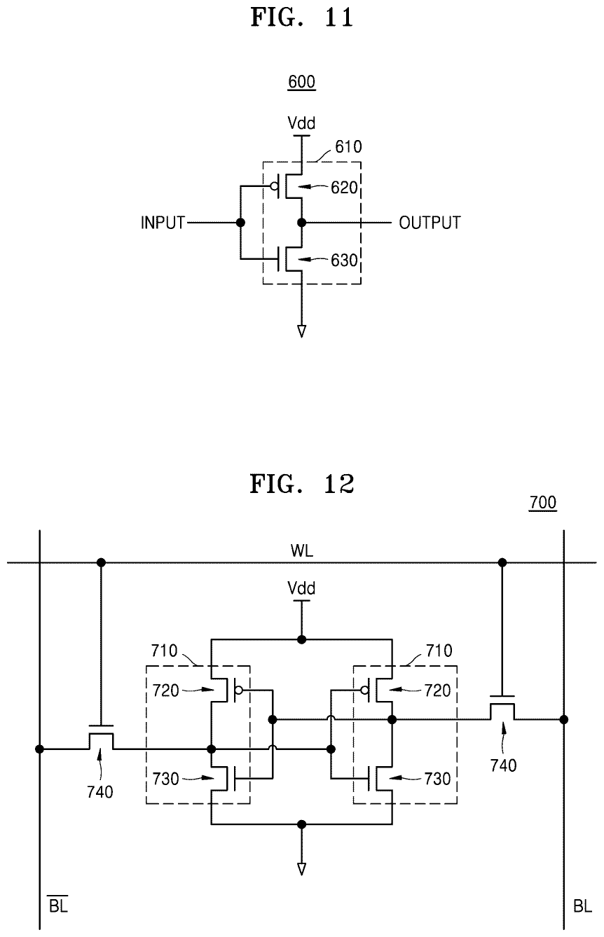

FIG. 11 is a circuit diagram of a CMOS inverter according to an embodiment.

Referring to FIG. 11, a CMOS inverter 600 includes a CMOS transistor 610. The CMOS transistor 610 includes a PMOS transistor 620 and an NMOS transistor 630 connected between a power terminal Vdd and a ground terminal. The CMOS transistor 610 may include any one of the semiconductor devices according to the embodiments described above with reference to FIGS. 1 to 9, or a semiconductor device modified and combined thereof.

FIG. 12 is a circuit diagram of a CMOS SRAM device 700 according to an embodiment.

Referring to FIG. 12, the CMOS SRAM device 700 includes a pair of driving transistors 710. Each of the pair of driving transistors 710 includes a PMOS transistor 720 and an NMOS transistor 730 connected between the power terminal Vdd and the ground terminal. The CMOS SRAM device 700 may further include a pair of transmission transistors 740. Sources of the transmission transistor 740 are cross-connected to common nodes of the PMOS transistor 720 and the NMOS transistor 730 constituting the driving transistor 710. A power terminal Vdd is connected to a source of the PMOS transistor 720, and a ground terminal is connected to a source of the NMOS transistor 730. A word line WL may be connected to a gate of each of a pair of transmission transistors 740, and a bit line BL and an inverted bit line may be connected to a drain of each of the pair of transmission transistors 740. At least one of the driving transistor 710 and the transmission transistor 740 of the CMOS SRAM device 700 may include any one of the semiconductor devices according to the embodiments described above with reference to FIGS. 1 to 9, or a semiconductor device modified and combined thereof.

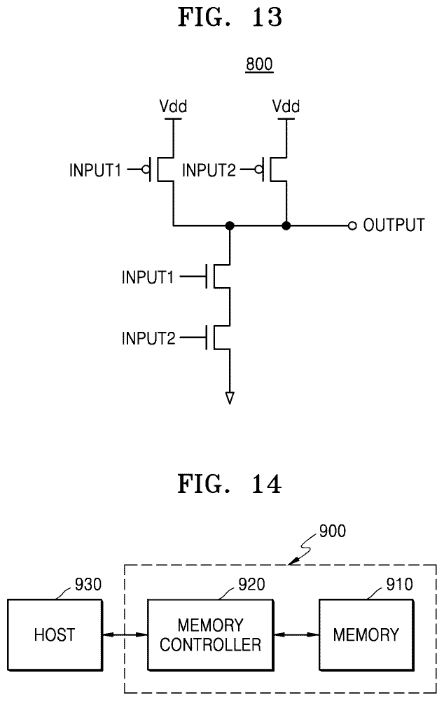

FIG. 13 is a circuit diagram of a CMOS NAND circuit according to an embodiment.

Referring to FIG. 13, the CMOS NAND circuit 800 includes a pair of CMOS transistors through which different input signals are transmitted. The CMOS NAND circuit 800 may include any one of the semiconductor devices according to the embodiments described above with reference to FIGS. 1 to 9, or a semiconductor device modified and combined thereof. FIG. 14 is a block diagram of an electronic device according to an embodiment.

Referring to FIG. 14, an electronic device 900 includes a memory 910 and a memory controller 920. The memory controller 920 may control the memory 910 to read data from the memory 910 and/or write data to the memory 910 in response to a request from a host 930. At least one of the memory 910 and the memory controller 920 may include any one of the semiconductor devices according to the embodiments described above with reference to FIGS. 1 to 9, or a semiconductor device modified and combined thereof.

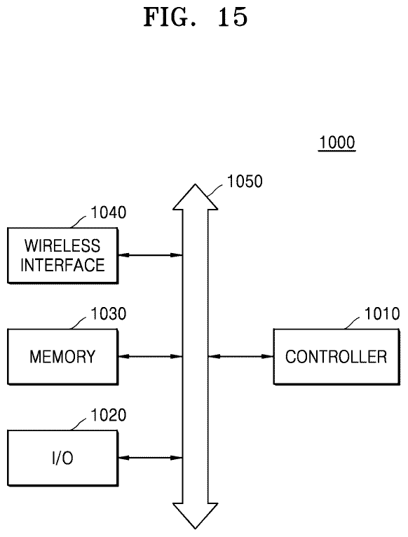

FIG. 15 is a block diagram of an electronic device according to another embodiment.

Referring to FIG. 15, an electronic device 1000 may configure a wireless communication device or a device capable of transmitting and/or receiving information under a wireless environment. The electronic device 1000 includes a controller 1010, an input/output device (I/O) 1020, a memory 1030, and a wireless interface 1040, which are interconnected through a bus 1050.

The controller 1010 may include at least one of a microprocessor, a digital signal processor, or a processing device similar thereto. The input/output device 1020 may include at least one of a keypad, a keyboard, and a display. The memory 1030 may be used to store commands to be executed by the controller 1010. For example, the memory 1030 may be used to store user data. The electronic device 1000 may use the wireless interface 1040 to transmit/receive data through a wireless communication network. The wireless interface 1040 may include an antenna and/or a wireless transceiver. In some configurations, the electronic device 1000 may be used in communication interface protocols for third-generation communication systems, such as code division multiple access (CDMA), global system for mobile communications (GSM), North American digital cellular (NADC), extended-time division multiple access (E-TDMA), and/or wide band code division multiple access (WCDMA). The electronic device 1000 may include any one of the semiconductor devices according to the embodiments described above with reference to FIGS. 1 to 9, or a semiconductor device modified and combined thereof.

The semiconductor device according to the embodiments may exhibit good electrical performance in a micro-structure, and thus may be applied to an integrated circuit device, and may implement miniaturization, low power, and high performance.

The semiconductor device according to embodiments may include, in a channel layer, a first two-dimensional material layer including a noble metal-based two-dimensional semiconductor material and a second two-dimensional semiconductor material layer different from the first two-dimensional semiconductor material layer, and may reduce contact resistance between the two-dimensional material layer and the electrode by using the two-dimensional semiconductor material layer including the noble metal material.

The semiconductor device according to the embodiments may easily remove impurities generated during the manufacturing process by placing the first two-dimensional material layer having high chemical stability outside the channel layer, and may easily adjust the thickness of the channel layer by controlling the number of layers of the noble metal-based first and second two-dimensional material layers included in the channel layer.

The semiconductor devices 100, 100a, 100b, 100c, 100d, 100e, and 100f may be modified to provide memory devices by forming a data storage element (e.g., capacitor) connected to the drain electrode 152, where the data storage element may be separated from the gate electrode 160. Such a memory device may be used in the memory block 508 in FIG. 10, memory 910 in FIG. 14, and/or memory 1030 in FIG. 15, but example embodiments are not limited thereto.

The semiconductor device and the electronic device including the same have been described with reference to the embodiments illustrated in the drawings.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A semiconductor device comprising:
a channel layer including a channel region, a source region, and a drain region, the source region and the drain region on both sides of the channel region, respectively;
a source electrode connected to the source region;
a drain electrode connected to the drain region; and
a gate electrode on the channel region, wherein
the channel region includes a first two-dimensional material layer and a second two-dimensional material layer,
the first two-dimensional material layer includes a noble metal-based two-dimensional semiconductor material, and
the second two-dimensional material layer includes a two-dimensional semiconductor material,
the two-dimensional semiconductor material of the second two-dimensional material layer is different from the noble metal-based two-dimensional semiconductor material of the first two-dimensional material layer.

2. The semiconductor device of claim 1, wherein
the first two-dimensional material layer comprises at least one of Pt, Ag, Pd, Ir, Ru, Au, Os, and Rd, and
the first two-dimensional material layer comprises at least one of S, Se, and Te.

3. The semiconductor device of claim 1, wherein the second two-dimensional material layer comprises a transition metal dichalcogenide (TMD) material.

4. The semiconductor device of claim 3, wherein
the TMD material comprises at least one of Mo, W, Nb, V, Ta, Ti, Zr, Hf, Tc, Re, Cu, Ga, In, Sn, Ge, and Pb, and
the TMD material comprises at least one of S, Se, and Te.

5. The semiconductor device of claim 1, wherein the first two-dimensional material layer is on each of an uppermost portion of the channel layer and a lowermost portion of the channel layer.

6. The semiconductor device of claim 1, wherein a number of layers of the first two-dimensional material layer on each of an uppermost portion of the channel layer and a lowermost portion of the channel layer is one to three.

7. The semiconductor device of claim 1, wherein a number of layers of the second two-dimensional material layer is one to ten.

8. The semiconductor device of claim 1, wherein the source region and the drain region each comprise the first two-dimensional material layer and the second two-dimensional material layer.

9. The semiconductor device of claim 1, wherein the source region and the drain region each comprise the first two-dimensional material layer in plural form to provide a plurality of first two-dimensional material layers.

10. The semiconductor device of claim 9, wherein a portion of the plurality of first two-dimensional material layers forms a lateral junction with the second two-dimensional material layer.

11. The semiconductor device of claim 9, wherein a number of layers of the plurality of first two-dimensional material layers is four or more.

12. The semiconductor device of claim 1, wherein the gate electrode is on an upper portion of the channel region or a lower portion of the channel region.

13. A semiconductor device comprising:
a first channel layer including a first channel region, a first source region, and a first drain region, the first source region and the first drain region being provided on both sides of the first channel region, respectively;
a second channel layer spaced apart from the first channel layer and including a second channel region, a second source region, and a second drain region, the second source region and the second drain region being respectively provided on both sides of the second channel region;
a source electrode connected to the first source region and the second source region;
a drain electrode connected to the first drain region and the second drain region; and
a gate electrode surrounding the first channel region and the second channel region, wherein
the first channel region and the second channel region each include a first two-dimensional material layer including a noble metal-based two-dimensional semiconductor material and a second two-dimensional material layer including a two-dimensional semiconductor material different from the first two-dimensional material layer.

14. The semiconductor device of claim 13, wherein
the first two-dimensional material layer comprises at least one of Pt, Ag, Pd, Ir, Ru, Au, Os, and Rd, and
the first two-dimensional material layer comprises at least one of S, Se, and Te.

15. The semiconductor device of claim 14, wherein the second two-dimensional material layer comprises a transition metal dichalcogenide (TMD) material.

16. The semiconductor device of claim 15, wherein
the TMD material comprises at least one of Mo, W, Nb, V, Ta, Ti, Zr, Hf, Tc, Re, Cu, Ga, In, Sn, Ge, and Pb, and
the TMD material comprises at least one of S, Se, and Te.

17. The semiconductor device of claim 13, wherein the first two-dimensional material layer is on each of an uppermost portion of the first channel layer, an uppermost portion of the second channel layer, a lowermost portion of the first channel layer, and a lowermost portion of the second channel layer.

18. The semiconductor device of claim 13, wherein the first source region and the first drain region each comprise the first two-dimensional material layer and the second two-dimensional material layer.

19. The semiconductor device of claim 13, wherein the first source region and the first drain region each comprise first two-dimensional material layer in plural form to provide a plurality of first two-dimensional material layers.

20. The semiconductor device of claim 19, wherein a portion of the plurality of first two-dimensional material layers forms a lateral junction with the second two-dimensional material layer.
